(19) United States
(12) Patent Application Publication
(10) Pub. No.: US 2026/0190573 A1
(43) Pub. Date: Jul. 2, 2026

(54) STRETCHABLE DISPLAY DEVICE AND METHOD OF MANUFACTURING THE SAME

(71) Applicant: LG Display Co., Ltd., Seoul (KR)

(72) Inventor: Se-Jin JANG, Paju-si (KR)

(73) Assignee: LG Display Co., Ltd., Seoul (KR)

(21) Appl. No.: 19/223,889

(22) Filed: May 30, 2025

(30) Foreign Application Priority Data
Dec. 30, 2024 (KR) 10-2024-0200955

(51) Int. Cl. H10H 29/49; H10H 29/01

(52) U.S. Cl. CPC H10H 29/49; H10H 29/012

(57) ABSTRACT

A stretchable display device includes a lower base substrate in which a rigid portion and a soft portion are defined, a light-emitting element disposed in the rigid portion, a lower connection line disposed in the soft portion, an upper base substrate disposed on the lower base substrate, and an upper connection line disposed on the upper base substrate. The upper connection line is electrically connected to the lower connection line.

### CROSS-REFERENCE TO RELATED APPLICATION

The present application claims priority to Korean Patent Application No. 10-2024-0200955 filed in the Republic of Korea on Dec. 30, 2024, the entire contents of which are hereby expressly incorporated by reference into the present application.

### BACKGROUND

### Technical Field

The present disclosure relates to a display device, and more particularly, to a stretchable display device.

### Discussion of the Related Art

As the information society progresses, interest in displays that process and display a large amount of information has been increasing, and various types of displays have been developed.

Accordingly, in addition to a commonly known rectangular display, flexible display devices such as a bendable display device for gaming, a foldable display device capable of being folded and unfolded, and a rollable display device having optimal space utilization have been widely developed.

Recently, a stretchable display device, which is much more flexible than these flexible display devices, has been in the spotlight as a next-generation display.

The stretchable display device is a display that can freely transform the shape of a screen without distortion even when the size of the screen is increased, folded, or twisted. Unlike the bendable, foldable, or rollable display devices that may only be transformed in a specific area or direction, the stretchable display device is able to implement the ultimate free-form and is considered as the most suitable display for the era of the Internet of Things (IoT), 5G, and autonomous vehicles.

The stretchable display device can include a rigid portion in which a pixel is disposed and a soft portion in which a connection line connecting the pixels is disposed. The rigid portion may not be stretched, and the soft portion can be stretched.

In order to secure stretching properties, the connection line can be configured to have a relatively narrow width and include at least one curved part, and the shape of the connection line can be changed during the stretching process. Accordingly, the connection line can be cut-off when continuously stretched.

In addition, since there is no separate protection layer on the connection line other than a flexible substrate, the connection line can be easily affected by external impacts and be damaged.

### SUMMARY OF THE DISCLOSURE

Accordingly, embodiments of the present disclosure are directed to a stretchable display device that substantially obviates one or more of the problems due to limitations and disadvantages of the related art.

An aspect of the present disclosure is to provide a stretchable display device capable of preventing a connection line from being damaged.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

To achieve these and other aspects of the inventive concepts, as embodied and broadly described herein, a stretchable display device includes a lower base substrate in which a rigid portion and a soft portion are defined; a light-emitting element disposed in the rigid portion; a lower connection line disposed in the soft portion; an upper base substrate disposed on the lower base substrate; and an upper connection line disposed on the upper base substrate, wherein the upper connection line is electrically connected to the lower connection line.

In another aspect of the present disclosure, a method of manufacturing a stretchable display device includes forming a lower base substrate in which a rigid portion and a soft portion are defined; forming a lower connection line in the soft portion; transferring a light-emitting element in the rigid portion; forming an upper base substrate; forming an upper connection line on the upper base substrate; and attaching the lower base substrate and the upper base substrate such that the upper connection line and the lower connection line overlap and face each other, wherein the upper base substrate is spaced apart from the rigid portion and overlaps the soft portion.

It is to be understood that both the foregoing general description and the following detailed description are example and explanatory and are intended to provide further explanation of the inventive concepts as claimed.

### BRIEF DESCRIPTION OF THE DRAWINGS

The accompanying drawings, which are included to provide a further understanding of the disclosure and which are incorporated in and constitute a part of this application, illustrate embodiments of the disclosure and together with the description serve to explain various principles of the disclosure. In the drawings:

FIG. 1 is a schematic cross-sectional view of a stretchable display device according to embodiments of the present disclosure;

FIG. 2A is a schematic cross-sectional view of the stretchable display device in the non-stretched state according to the embodiments of the present disclosure, and FIG. 2B is a schematic cross-sectional view of the stretchable display device in the stretched state according to the embodiments of the present disclosure;

FIG. 3 is a schematic plan view of a stretchable display device according to the embodiments of the present disclosure;

FIG. 4 is a schematic plan view of a lower substrate of the stretchable display device according to the embodiments of the present disclosure;

FIG. 5 is a schematic plan view of an upper substrate of the stretchable display device according to the embodiments of the present disclosure;

FIG. 6 is a schematic plan view of an intermediate layer of the stretchable display device according to the embodiments of the present disclosure;

FIG. 7 is a schematic cross-sectional view corresponding to line I-I′ of FIG. 4;

FIG. 8 is a schematic cross-sectional view corresponding to line II-II′ of FIG. 5;

FIGS. 9A to 9F are schematic cross-sectional views of the lower substrate of the stretchable display device in steps of manufacturing the same according to the embodiments of the present disclosure;

FIGS. 10A to 10C are schematic cross-sectional views of the upper substrate of the stretchable display device in steps of manufacturing the same according to the embodiments of the present disclosure;

FIGS. 11A to 11G are schematic cross-sectional views of the stretchable display device in steps of manufacturing the same according to the embodiments of the present disclosure;

FIGS. 12A and 12B are schematic cross-sectional views of a stretchable display device in steps of manufacturing the same according to another embodiment of the present disclosure; and

FIG. 13A is a schematic cross-sectional view of a stretchable display device ideally aligned according to an embodiment of the present invention, and FIG. 13B is a schematic cross-sectional view of a stretchable display device misaligned according to an embodiment of the present invention.

### DETAILED DESCRIPTION OF THE EMBODIMENTS

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals refer to the same components throughout this disclosure.

Further, in the following description of the present disclosure, when a detailed description of a known related art is determined to unnecessarily obscure the gist of the present disclosure, the detailed description thereof will be omitted herein or can be briefly discussed.

When terms such as “including,” “having,” “comprising” and the like mentioned in this disclosure are used, other parts can be added unless the term “only” is used herein.

Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

As used herein, the terms “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner. For example, the term “in contact with,” as used herein, encompasses both “indirect contact” and “direct contact.” Accordingly, when the phrase “A is in contact with B” is used, it implies that other components can be present between A and B, unless explicitly specified as “A is in direct contact with B.”

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure.

Features of various embodiments of the present disclosure can be partially or entirely united or combined with each other, technically various interlocking and driving are possible, and each of the embodiments can be independently implemented with respect to each other or implemented together in a related relationship. Further, the term “can” fully encompasses all the meanings and coverages of the term “may” and vice versa.

Hereinafter, example embodiments of the present disclosure will be described in detail with reference to accompanying drawings. All the components of each display device according to all embodiments of the present disclosure are operatively coupled and configured.

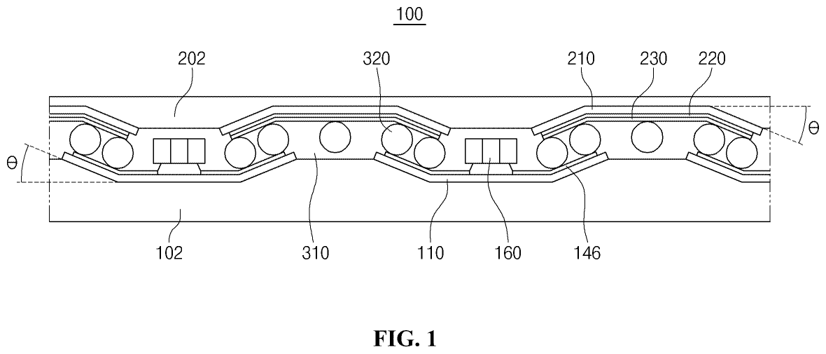

A stretchable display device according to one or more embodiments of the present disclosure can include a lower substrate provided with a light-emitting element and a lower connection line and an upper substrate provided with an upper connection line, and the lower connection line and the upper connection line can be electrically connected to each other through conductive balls. In addition, flexible substrates can be provided on outer surfaces of the lower substrate and the upper substrate, respectively. The stretchable display device according to the embodiment of the present disclosure will be described in detail with reference to FIG. 1.

FIG. 1 is a schematic cross-sectional view of a stretchable display device according to embodiments of the present disclosure.

Referring to FIG. 1, the stretchable display device 100 according to the embodiments of the present disclosure can include a first flexible substrate 102 and a second flexible substrate 202 facing and being spaced apart from each other.

The first flexible substrate 102 and the second flexible substrate 202 can be formed of a soft matter or soft material with bending or stretching properties. For example, the first flexible substrate 102 and the second flexible substrate 202 can be formed of silicone rubber such as polydimethylsiloxane (PDMS), elastomer such as polyurethane (PU), or styrene butadiene block copolymer such as styrene butadiene styrene (SBS), among others.

In addition, the first flexible substrate 102 and the second flexible substrate 202 can have different thicknesses depending on the location. The first flexible substrate 102 and the second flexible substrate 202 can have different minimum thicknesses. Here, the minimum thickness of the second flexible substrate 202 can be smaller than the minimum thickness of the first flexible substrate 102. For example, the minimum thickness of the first flexible substrate 102 can be greater than 10 μm and equal to or less than 1 mm.

Meanwhile, the surface hardness of the stretchable display device 100 can increase as the minimum thickness of the second flexible substrate 202 decreases. The minimum thickness of the second flexible substrate 202 can be equal to or less than 10 μm. However, embodiments of the present disclosure are not limited thereto.

A plurality of lower base substrates 110 can be provided on an upper surface of the first flexible substrate 102 and be spaced apart from each other. A plurality of upper base substrates 210 can be provided on a lower surface of the second flexible substrate 202 and be spaced apart from each other. A pixel can be provided on each lower base substrate 110, and the pixel can include a plurality of sub-pixels.

The lower base substrates 110 can partially overlap the upper base substrates 210 adjacent thereto. In this case, adjacent lower base substrates 110 can overlap one upper base substrate 210, and adjacent upper base substrates 210 can overlap one lower base substrate 110.

An overlap area of the lower base substrate 110 and the upper base substrate 210, for example, edge portions of the lower base substrate 110 and the upper base substrate 210 can be inclined with respect to center portions thereof. Here, an inclination angle θ of the edge portion can be within a range of 10 degrees to 70 degrees, and preferably 20 degrees to 45 degrees.

The lower base substrate 110 and the upper base substrate 210 can be formed of a rigid material having lower flexibility than the soft material of the first and second flexible substrates 102 and 202. For example, the lower base substrate 110 and the upper base substrate 210 can be formed of a polyimide (PI) resin or epoxy resin, among others.

The lower base substrate 110 and the upper base substrate 210 can have relatively high elastic modulus, and the elastic modulus of the lower base substrate 110 and the upper base substrate 210 can be higher than the elastic modulus of the first flexible substrate 102 and the second flexible substrate 202.

A light-emitting element 160 and a lower connection line 146 can be provided on the lower base substrate 110, i.e., on an upper surface of the lower base substrate 110. A light-blocking layer 220 and an upper connection line 230 can be provided under the upper base substrate 210, i.e., on a lower surface of the upper base substrate 210. An intermediate layer 310 containing conductive balls 320 can be provided between the lower connection line 146 and the upper connection line 230. Here, the light-emitting element 160 can be disposed to correspond to each sub-pixel, and the conductive balls 320 may not be provided on the light-emitting element 160.

The lower connection line 146 and the upper connection line 230 adjacent to each other can partially overlap each other. The lower connection line 146 and the upper connection line 230 overlapping each other can be electrically connected to each other through the conductive balls 320. In this case, the upper connection line 230 provided on one upper base substrate 210 can overlap and be electrically connected to the lower connection lines 146 of two lower base substrates 110 adjacent thereto.

Accordingly, in the stretchable display device 100 according to the embodiments of the present disclosure, the pixels provided on the adjacent lower base substrates 110 can be connected to each other through the upper connection line 230 of the upper base substrate 210, thereby transmitting signals.

The stretchable display device 100 according to the embodiments of the present disclosure can be stretched, and during the stretching process, shapes of the lower connection line 146 and the upper connection line 230 may not be changed.

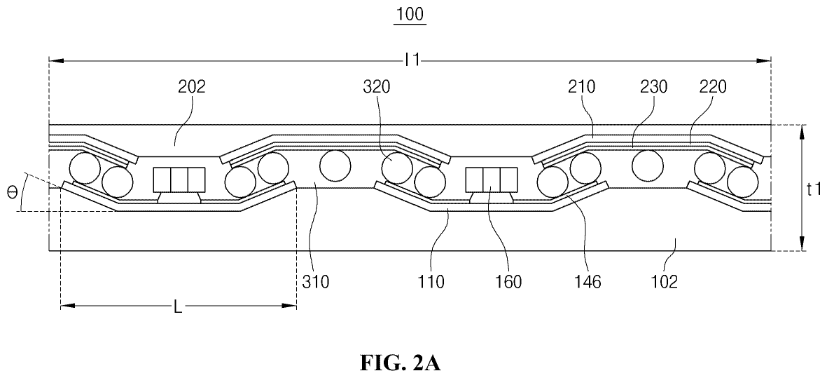

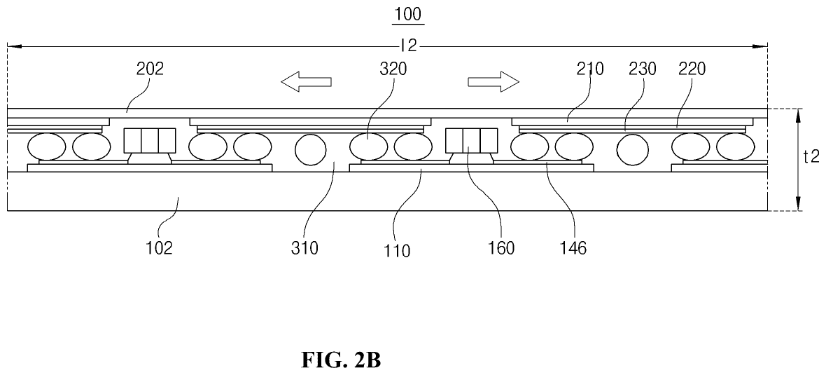

The stretchable display device 100 according to the embodiments of the present disclosure in a stretched state and in a non-stretched state will be described with reference to FIG. 2A and FIG. 2B.

FIG. 2A is a schematic cross-sectional view of the stretchable display device in the non-stretched state according to the embodiments of the present disclosure, and FIG. 2B is a schematic cross-sectional view of the stretchable display device in the stretched state according to the embodiments of the present disclosure.

Referring to FIG. 2A, in the stretchable display device 100 of the non-stretched state according to the embodiments of the present disclosure, both edge portions of each of the lower base substrate 110 and the upper base substrate 210 can be inclined with respect to the center portion thereof.

The stretchable display device 100 of the non-stretched state can have a first length l1 and a first thickness t1.

Next, referring to FIG. 2B, the stretchable display device 100 according to the embodiments of the present disclosure can be stretched in the plane direction. In this case, the first and second flexible substrates 102 and 202 and the intermediate layer 310 can be extended in the plane direction, and the both edge portions of each of the lower base substrate 110 and the upper base substrate 210 can be spread out.

Accordingly, in the stretchable display device 100 of the stretched state according to the embodiments of the present disclosure, the both edge portions of each of the lower base substrate 110 and the upper base substrate 210 can be parallel to and may not be inclined with respect to the center portion thereof.

Meanwhile, in the stretched state, the conductive balls 320 can be pressed in the thickness direction to be stronger contact with the lower connection line 146 and the upper connection line 230 and may not be separated from the lower connection line 146 and the upper connection line 230.

The stretchable display device 100 of the stretched state can have a second length l2 and a second thickness t2. Here, the second length l2 can be greater than the first length l1, and the second thickness t2 can be smaller than the first thickness t1.

In this case, an elongation ratio X can have a relationship of L: L(cos θ)=X:100, for example, X=100/(cos θ). Here, L is a length of the lower base substrate 110 in the non-stretched state, θ is the inclination angle of the lower base substrate 110, and L(cos θ) is a length of the lower base substrate 110 in the stretched state.

For example, when the inclination angle θ is 25 degrees, the elongation ratio X can be about 110. For example, the stretchable display device 100 according to the embodiments of the present disclosure can be stretched by about 10%.

As such, the adjacent pixels can be connected to each other through the lower connection line 146 and the upper connection line 230, so that the stretchable display device 100 according to the embodiments of the present disclosure can be stretched without changing the shapes of the lower connection line 146 and the upper connection line 230. Accordingly, it is possible to prevent the lower connection line 146 and the upper connection line 230 from being damaged.

In addition, since the lower base substrate 110 is disposed between the lower connection line 146 and the first flexible substrate 102 and the upper base substrate 210 is disposed between the upper connection line 230 and the second flexible substrate 202, the lower connection line 146 and the upper connection line 230 can be prevented from being damaged due to external impacts.

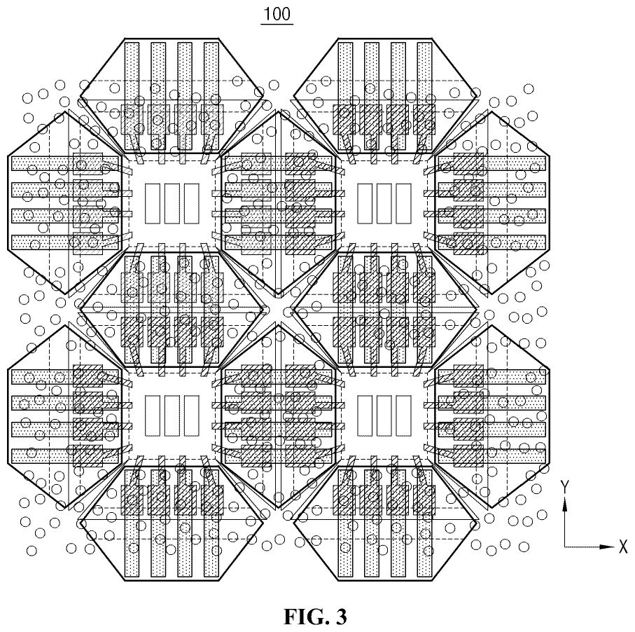

The specific configuration of the stretchable display device 100 according to the embodiments of the present disclosure will be described in detail with reference to FIGS. 3 to 8.

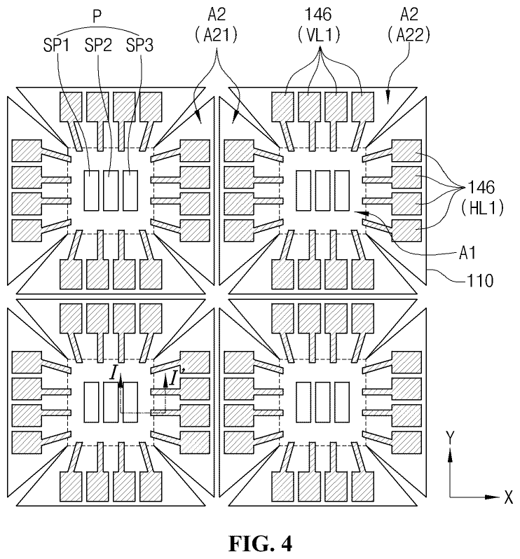

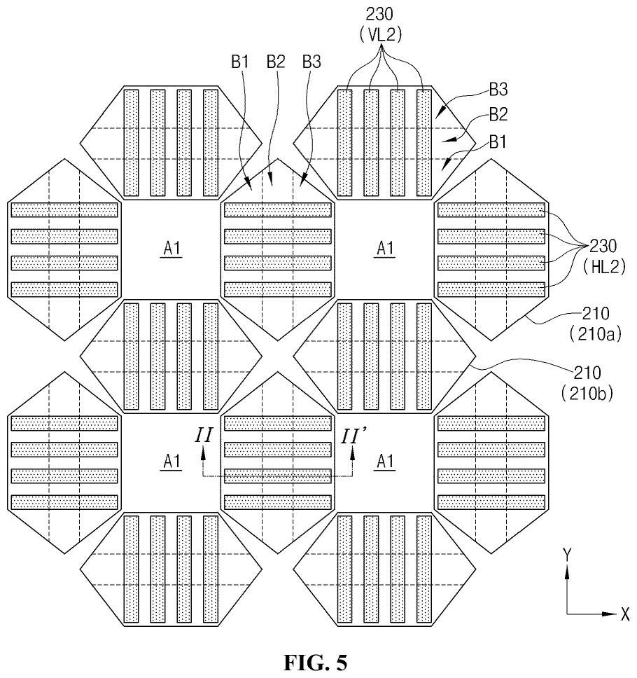

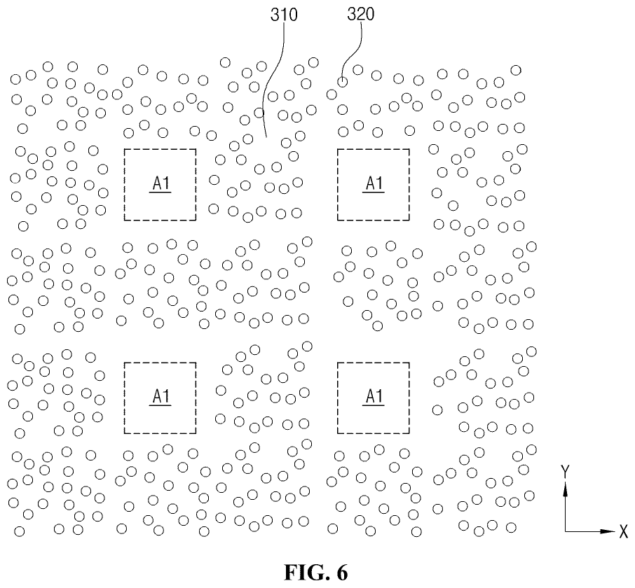

FIG. 3 is a schematic plan view of a stretchable display device according to the embodiments of the present disclosure, FIG. 4 is a schematic plan view of a lower substrate of the stretchable display device according to the embodiments of the present disclosure, FIG. 5 is a schematic plan view of an upper substrate of the stretchable display device according to the embodiments of the present disclosure, and FIG. 6 is a schematic plan view of an intermediate layer of the stretchable display device according to the embodiments of the present disclosure. Here, for convenience of illustration, the lower substrate and the upper substrate of the stretchable display device according to the embodiments of the present disclosure can be shown as being non-stretched and not being inclined.

Referring to FIGS. 3 to 6, the stretchable display device 100 according to the embodiments of the present disclosure can include the lower substrate, the upper substrate, and the intermediate layer 310. The lower substrate can include the lower base substrate 110, the pixel P, and the lower connection line 146. The upper substrate can include the upper base substrate 210 and the upper connection line 230. The intermediate layer 310 can include the plurality of conductive balls 320 therein.

Specifically, referring to FIG. 4, in the lower substrate of the stretchable display device 100 according to the embodiments of the present disclosure, the plurality of lower base substrate 110 can be spaced apart from each other in a first direction X and a second direction Y. A rigid portion A1 and a soft portion A2 can be defined in each lower base substrate 110. The soft portion A2 can be disposed on each of both sides of the rigid portion A1 in the first direction X and the second direction Y.

The rigid portion A1 can have a substantially rectangular shape, and the soft portion A2 can have a substantially trapezoidal shape. However, embodiments of the present disclosure are not limited thereto, and the shapes of the rigid portion A1 and the soft portion A2 can vary.

The pixel P including the plurality of sub-pixels SP1, SP2, and SP3 can be provided in the rigid portion A1. For example, first, second, and third sub-pixels SP1, SP2, and SP3 can be provided in the rigid portion A1, and the first, second, and third sub-pixels SP1, SP2, and SP3 can be red, green, and blue sub-pixels, respectively.

Each of the first, second, and third sub-pixels SP1, SP2, and SP3 can include a light-emitting element, at least one transistor, and at least one capacitor, and this will be described in detail later.

The lower connection line 146 can be provided in the soft portion A2. For example, four lower connection lines 146 can be provided in one soft portion A2. The lower connection line 146 can include a plurality of voltage lines such as a gate line, a data line, a high potential line, a low potential line, an emission signal line, and a reference voltage line. Here, a width of the lower connection line 146 far from the rigid portion A1 can be greater than a width of the lower connection line 146 adjacent to the rigid portion A1.

The soft portion A2 can include a horizontal soft portion A21 and a vertical soft portion A22. The horizontal soft portion A21 can be disposed on each of both sides of the rigid portion A1 in the first direction X, and the vertical soft portion A22 can be disposed on each of both sides of the rigid portion A1 in the second direction Y.

The horizontal soft portion A21 and the vertical soft portion A22 adjacent to each other can be spaced apart from each other. A distance between the horizontal soft portion A21 and the vertical soft portion A22 adjacent to each other can increase as a distance from the rigid portion A1 increases.

Meanwhile, the lower connection line 146 can include a horizontal lower connection line HL1 and a vertical lower connection line VL1. The horizontal lower connection line HL1 can be disposed in the horizontal soft portion A21, and the vertical lower connection line VL1 can be disposed in the vertical soft portion A22.

For example, the horizontal lower connection line HL1 can include a gate line, a high potential line, a low potential line, and an emission signal line. The vertical lower connection line VL2 can include a plurality of data lines and a reference voltage line. However, embodiments of the present disclosure are not limited thereto.

Next, referring to FIG. 5, in the upper substrate of the stretchable display device 100 according to the embodiments of the present disclosure, the plurality of upper base substrates 210 can be spaced apart from each other in the first direction X and the second direction Y.

First, second, and third link portions B1, B2, and B3 can be defined in each upper base substrate 210 in the first direction x or the second direction Y. The second link portion B2 can be disposed between the first link portion B1 and the third link portion B3. The first link portion B1 and the third link portion B3 can be symmetrical with respect to the second link portion B2.

The first link portion B1 and the third link portion B3 can have a trapezoidal shape, and the second link portion B2 can have a hexagonal shape. Accordingly, the upper base substrate 210 can have a hexagonal shape. However, embodiments of the present disclosure are not limited thereto, and the shapes of the first, second, and third link portions B1, B2, and B3 and the upper base substrate 210 can vary.

The upper base substrate 210 can be spaced apart from the rigid portion A1 of the lower base substrate 110 and overlap the soft portion A2 of the lower base substrate 110. In this case, the first link portion B1 of one upper base substrate 210 can overlap the soft portion A2 of one of adjacent lower base substrates 110 in the first direction X or the second direction Y, and the third link portion B3 of the one upper base substrate 210 can overlap the soft portion A2 of the other of the adjacent lower base substrates 110 in the first direction X or the second direction Y.

The upper connection line 230 can be provided in the upper base substrate 210. For example, four upper connection lines 230 can be provided in one upper base substrate 210.

The upper base substrate 210 can include a horizontal base substrate 210a and a vertical base substrate 210b. The horizontal base substrate 210a can be disposed on each of both sides of the rigid portion A1 in the first direction X, and the vertical base substrate 210b can be disposed on each of both sides of the rigid portion A1 in the second direction Y. Accordingly, the horizontal base substrate 210a can be disposed between adjacent rigid portions A1 in the first direction X, and the vertical base substrate 210b can be disposed between adjacent rigid portions A1 in the second direction Y.

In addition, the horizontal base substrate 210a can overlap the soft portions A2 of adjacent lower base substrates 110 in the first direction X, and the vertical base substrate 210b can overlap the soft portions A2 of adjacent lower base substrates 110 in the second direction Y.

The horizontal base substrate 210a and the vertical base substrate 210b adjacent to each other can be spaced apart from each other. A distance between the horizontal base substrate 210a and the vertical base substrate 210b adjacent to each other can increase as a distance from the rigid portion A1 increases.

Meanwhile, referring to FIG. 6, the plurality of conductive balls 320 can be dispersed in the intermediate layer 310 of the stretchable display device 100 according to the embodiments of the present disclosure.

The intermediate layer 310 can be formed of one of soft materials of the first and second flexible substrates 102 and 202 mentioned above. In this case, the intermediate layer 310 can be formed of the same material as the first and second flexible substrates 102 and 202, but embodiments of the present disclosure are not limited thereto.

The plurality of conductive balls 320 can be disposed in an area except for the rigid portion A1 of the lower base substrate 110. For example, the plurality of conductive balls 320 can overlap the soft portion A2 of the lower base substrate 110 and can be spaced apart from the rigid portion A1.

The conductive ball 320 can include a polymer particle and a metal layer surrounding the polymer particle. For example, the conductive ball 320 can have a diameter of 3 μm to 15 μm. However, embodiments of the present disclosure are not limited thereto.

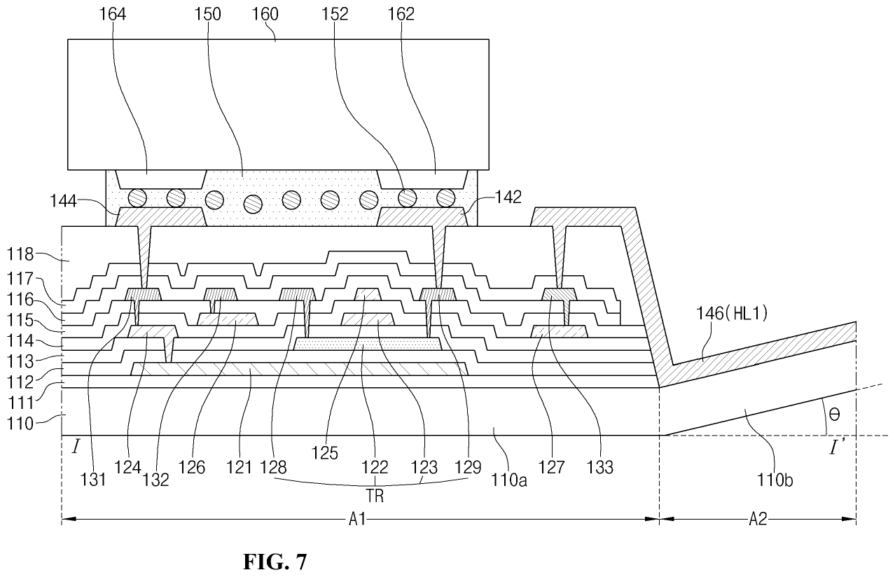

A cross-sectional configuration of the stretchable display device 100 according to the embodiments of the present disclosure will be described with reference to FIG. 7 and FIG. 8.

FIG. 7 is a schematic cross-sectional view of a lower substrate of the stretchable display device according to the embodiments of the present disclosure and shows a cross-section corresponding to line I-I′ of FIG. 4.

Referring to FIG. 7, the lower substrate of the stretchable display device 100 according to the embodiments of the present disclosure can include the lower base substrate 110 in which the rigid portion A1 and the soft portion A2 are defined. The lower base substrate 110 can include a first lower base portion 110a corresponding to the rigid portion A1 and a second lower base portion 110b corresponding to the soft portion A2.

The first lower base portion 110a and the second lower base portion 110b can be connected to each other and provided as one body. The second lower base portion 110b can be inclined with an inclination angle θ with respect to the first lower base portion 110a.

Next, a first buffer layer 111 can be provided on the lower base substrate 110. The first buffer layer 111 can be formed as a single layer or multiple layers of an inorganic insulating material. The inorganic insulating material of the first buffer layer 111 can include silicon nitride (SiNx), silicon oxide (SiOx), or silicon oxynitride (SiON).

In order to prevent damage of the first buffer layer 111 such as cracks due to stretching, the first buffer layer 111 can be provided only over the first lower base portion 110a and may not be provided over the second lower base portion 110b.

A light-shielding pattern 121 can be provided on the first buffer layer 111 of the rigid portion A1. The light-shielding pattern 121 can be formed of a conductive material such as metal. For example, the light-shielding pattern 121 can be formed of at least one of aluminum (Al), copper (Cu), molybdenum (Mo), titanium (Ti), chromium (Cr), nickel (Ni), tungsten (W), or an alloy thereof. The light-shielding pattern 121 can have a single-layered structure or a multiple-layered structure.

A second buffer layer 112 of an inorganic insulating material can be provided on the light-shielding pattern 121 of the rigid portion A1. A semiconductor layer 122 can be provided on the second buffer layer 112 of the rigid portion A1. The semiconductor layer 122 can overlap the light-shielding pattern 121.

The semiconductor layer 122 can include a channel region at its central part and source and drain regions at both sides of the channel region. The semiconductor layer 122 can be formed of an oxide semiconductor material or polycrystalline silicon.

A gate insulation layer 113 of an inorganic insulating material can be provided on the semiconductor layer 122 of the rigid portion A1. A gate electrode 123 and a first connection electrode 124 of a conductive material can be provided on the gate insulation layer 113 of the rigid portion A1.

The gate electrode 123 can overlap the semiconductor layer 122 and can be disposed to correspond to the central part of the semiconductor layer 122. The first connection electrode 124 can be in contact with the light-shielding pattern 121.

A first interlayer insulation layer 114 of an inorganic insulating material can be provided on the gate electrode 123 and the first connection electrode 124 of the rigid portion A1. An auxiliary electrode 125, an auxiliary line 126, and a pad electrode 127 of a conductive material can be provided on the first interlayer insulation layer 114 of the rigid portion A1.

A second interlayer insulation layer 115 of an inorganic insulating material can be provided on the auxiliary electrode 125, the auxiliary line 126, and the pad electrode 127 of the rigid portion A1. A source electrode 128, a drain electrode 129, a second connection electrode 131, and a power line 132 of a conductive material can be provided on the second interlayer insulation layer 115 of the rigid portion A1.

The source electrode 128 and the drain electrode 129 can be spaced apart from each other with the gate electrode 123 positioned therebetween and can be in contact with both ends of the semiconductor layer 122.

The semiconductor layer 122, the gate electrode 123, the source electrode 128, and the drain electrode 129 can constitute a thin film transistor TR.

The second connection electrode 131 can be in contact with the first connection electrode 124, and the power line 132 can be in contact with the auxiliary line 126. For example, the power line 132 can be a signal line supplying the low potential voltage ELVSS.

Next, a third interlayer insulation layer 116 of an inorganic insulating material can be provided on the source electrode 128, the drain electrode 129, the second connection electrode 131, and the power line 132 of the rigid portion A1. An auxiliary pad 133 of a conductive material can be provided on the third interlayer insulation layer 116 of the rigid portion A1. The auxiliary pad 133 can be in contact with the pad electrode 127.

A passivation layer 117 of an inorganic insulating material can be provided on the auxiliary pad 133 of the rigid portion A1. A planarization layer 118 can be provided on the passivation layer 117 of the rigid portion A1. The planarization layer 118 can eliminate a step difference due to the layers thereunder and can have a substantially flat top surface. The planarization layer 118 can be formed of an organic insulating material such as photosensitive acrylic polymer (photo acryl).

A first electrode 142, a second electrode 144, and the lower connection line 146 of a conductive material can be provided on the planarization layer 118 of the rigid portion A1. The first electrode 142 can be in contact with the drain electrode 129, and the second electrode 144 can be in contact with the second connection electrode 131.

For example, the first electrode 142, the second electrode 144, and the lower connection line 146 can be formed of a metal material such as aluminum (Al), molybdenum (Mo), or titanium (Ti) or can be formed of a transparent conductive material such as indium tin oxide (ITO). However, embodiments of the present disclosure are not limited thereto.

One end of the lower connection line 146 can be disposed on the planarization layer 118 of the rigid portion A1 and can be in contact with the auxiliary pad 133. The lower connection line 146 can extend into and also be provided in the soft portion A2. The lower connection line 146 can be in contact with a top surface of the second lower base portion 110b in the soft portion A2.

Meanwhile, a bank layer can be further provided on the first electrode 142, the second electrode 144, and the lower connection line 146 in the rigid portion A1.

Next, an element adhesive layer 150 can be provided on the first and second electrodes 142 and 144 of the rigid portion A1. The element adhesive layer 150 can be an anisotropic conductive film (ACF) including an insulating base member and a plurality of conductive balls 152 dispersed in the insulating base member.

The light-emitting element 160 can be provided on the element adhesive layer 150. The light-emitting element 160 can include a first element electrode 162 and a second element electrode 164. Here, the first element electrode 162 can be a p-electrode, and the second element electrode 164 can be an n-electrode. The first element electrode 162 can be an anode, and the second element electrode 164 can be a cathode. However, embodiments of the present disclosure are not limited thereto.

The light-emitting element 160 can be provided in the form of a micro light-emitting diode chip (micro LED chip or uLED chip) including the n-electrode, an n-type layer, an active layer, a p-type layer, and the p-electrode. The light-emitting element 160 can have a flip-chip structure. Alternatively, the light-emitting element 160 can have a lateral structure or a vertical structure.

The first element electrode 162 of the light-emitting element 160 can be electrically connected to the first electrode 142 through the conductive balls 152 of the element adhesive layer 150, and the second element electrode 164 can be electrically connected to the second electrode 144 through the conductive balls 152 of the element adhesive layer 150.

FIG. 8 is a schematic cross-sectional view of an upper substrate of the stretchable display device according to the embodiments of the present disclosure and shows a cross-section corresponding to line II-II′ of FIG. 5.

Referring to FIG. 8, the upper substrate of the stretchable display device 100 according to the embodiments of the present disclosure can include the upper base substrate 210 in which the first, second, and third link portions B1, B2, and B3 are defined.

A portion of the upper base substrate 210 corresponding to each of the first and third link portions B1 and B3 can be inclined with an inclination angle θ with respect to a portion of the upper base substrate 210 corresponding to the second link portion B2.

The light-blocking layer 220 can be provided on the upper base substrate 210. The light-blocking layer 220 can be provided substantially all over the upper base substrate 210 and can be formed along the inclination of the upper base substrate 210.

The light-blocking layer 220 can include a black component that absorbs light and can minimize internal reflection. For example, the light-blocking layer 220 can be formed of a resin containing a black pigment and/or carbon black, but is not limited thereto.

The light-blocking layer 220 can be omitted.

The upper connection line 230 of a conductive material can be provided on the light-blocking layer 220. The upper connection line 230 can be disposed on all of the first, second, and third link portions B1, B2, and B3. The upper connection line 230 can be formed along the inclination of the light-blocking layer 220 and the upper base substrate 210.

For example, the upper connection line 230 can be formed of a metal material such aluminum (Al), molybdenum (Mo), or titanium (Ti) or can be formed of a transparent conductive material such as indium tin oxide (ITO). However, embodiments of the present disclosure are not limited thereto.

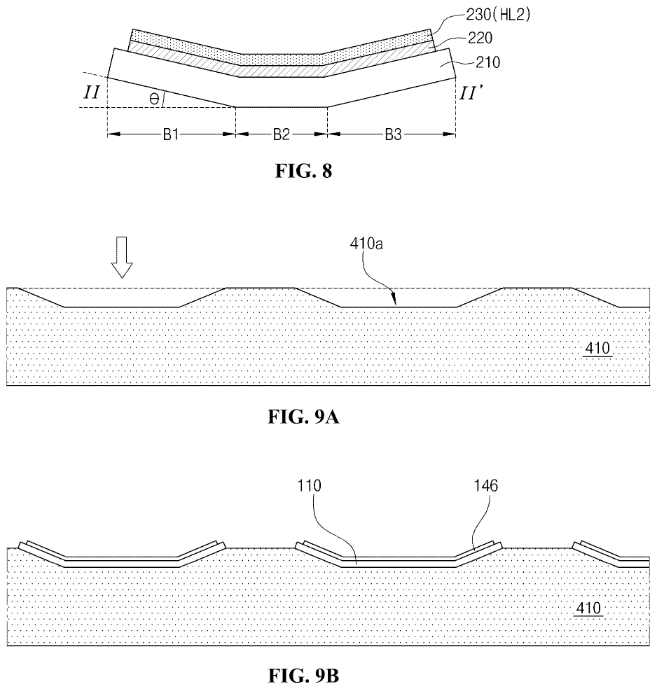

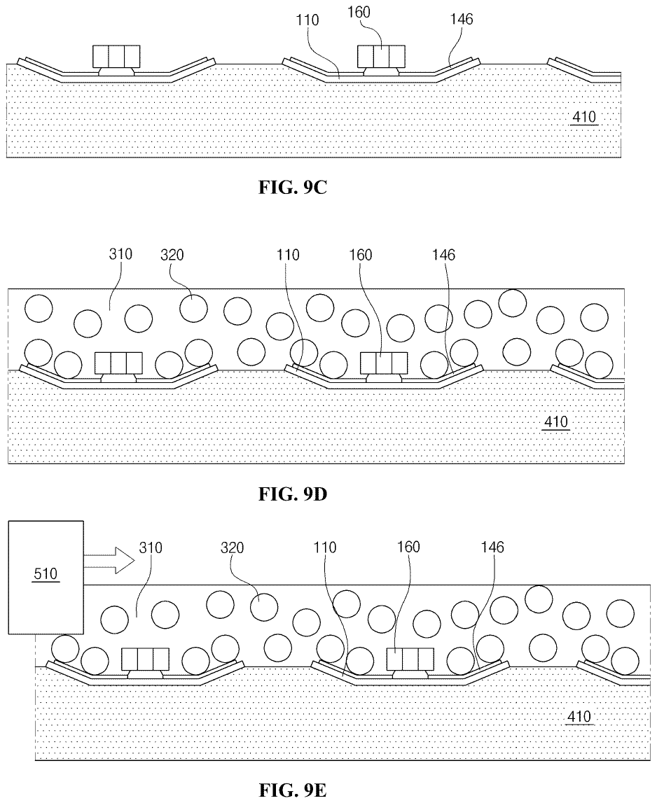

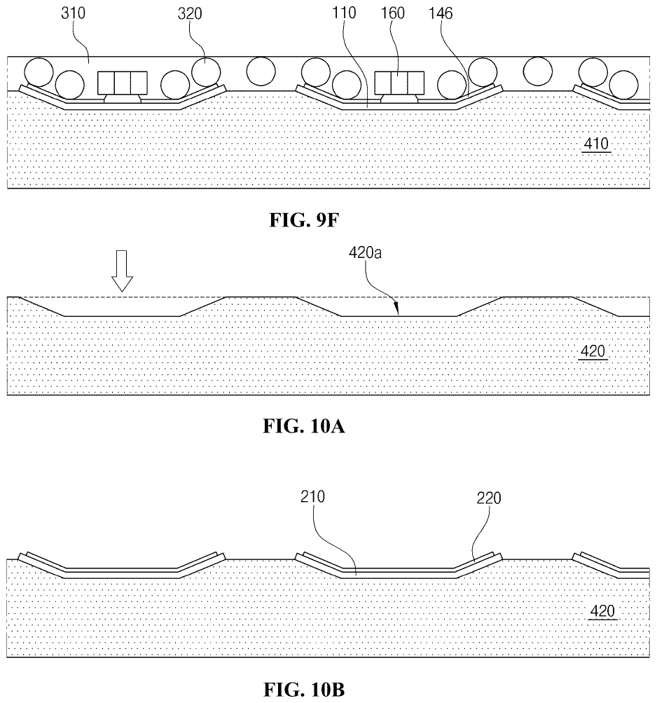

A method of manufacturing the stretchable display device according to the embodiments of the present disclosure including the lower substrate, the upper substrate, and the intermediate layer will be described with reference to FIGS. 9A to 9F, FIGS. 10A to 10C, and FIGS. 11A to 11G.

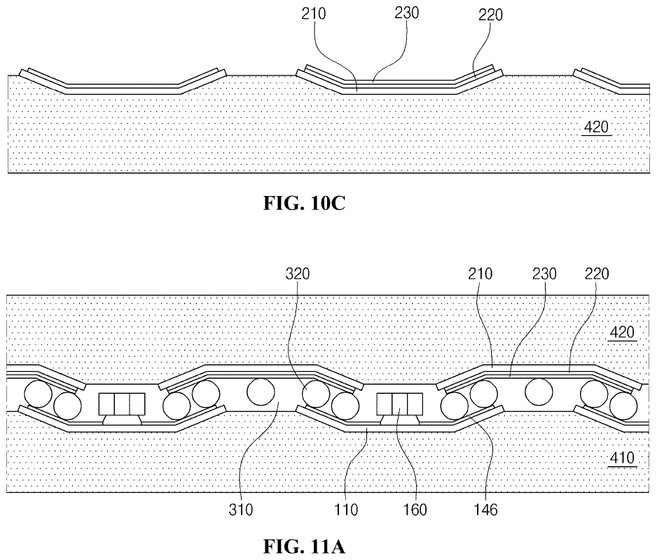

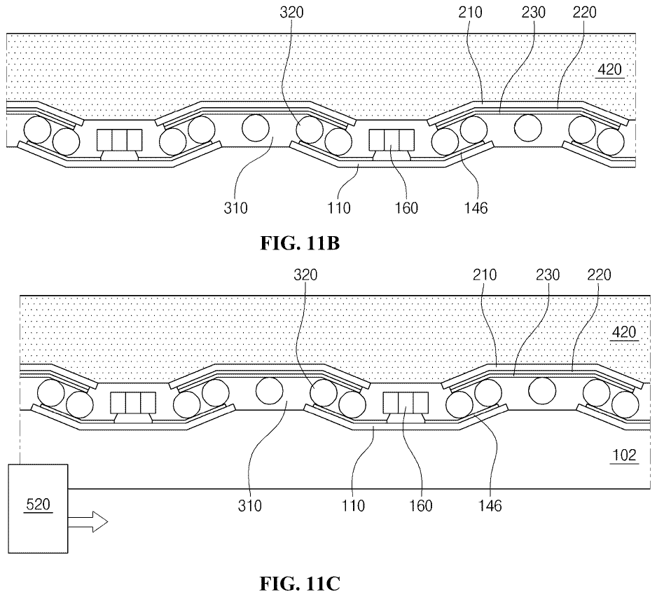

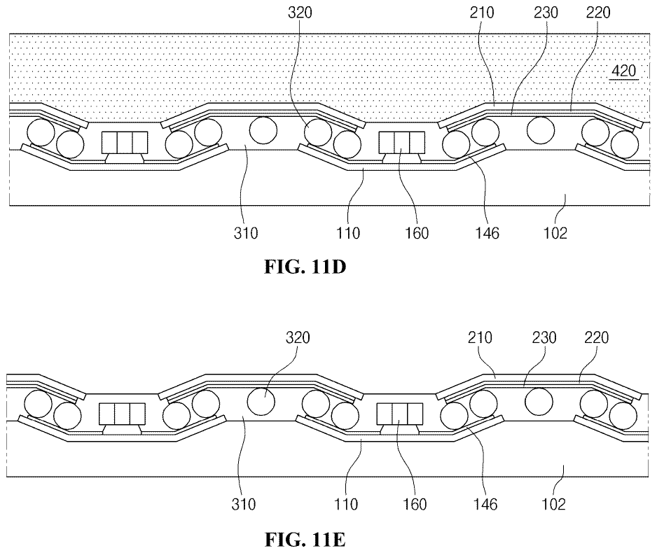

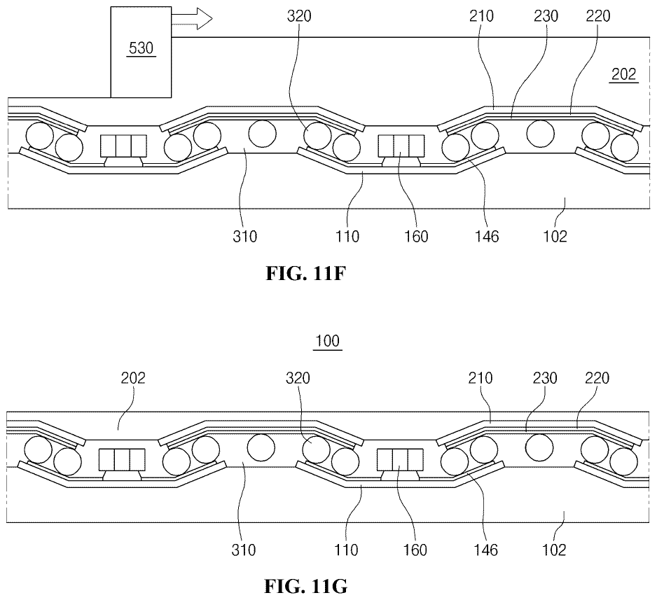

Particularly, FIGS. 9A to 9F are schematic cross-sectional views of the lower substrate of the stretchable display device in steps of manufacturing the same according to the embodiments of the present disclosure, FIGS. 10A to 10C are schematic cross-sectional views of the upper substrate of the stretchable display device in steps of manufacturing the same according to the embodiments of the present disclosure, and FIGS. 11A to 11G are schematic cross-sectional views of the stretchable display device in steps of manufacturing the same according to the embodiments of the present disclosure. FIGS. 9A to 9F, FIGS. 10A to 10C, and FIGS. 11A to 11G will be described with reference to FIGS. 3 to 8 together.

Referring to FIG. 9A, a first carrier substrate 410 can be provided, and an upper surface of the first carrier substrate 410 can be selectively removed by irradiating a laser, thereby forming a plurality of first concave portions 410a on the upper surface of the first carrier substrate 410. Here, the first carrier substrate 410 can be formed of glass.

Next, referring to FIG. 9B, the lower base substrate 110 can be formed on the first carrier substrate 410 to correspond to each of the first concave portions 410a. The lower connection line 146 can be formed on the lower base substrate 110.

As described above, the second lower base portion 110b of the lower base substrate 110 corresponding to the soft portion A2 can be inclined with respect to the first lower base portion 110a corresponding to the rigid portion A1, the lower connection line 146 can be provided over the inclined second base portion 110b, and a plurality of electrodes and lines electrically connected to the lower connection line 146 can be provided over the first base portion 110a.

Meanwhile, a sacrificial layer can be further provided between the first carrier substrate 410 and the lower base substrate 110. The sacrificial layer can be formed of an inorganic insulating material such as silicon oxide (SiOx) or silicon nitride (SiNx). Alternatively, the sacrificial layer can be formed of amorphous silicon (a-Si) or can be formed by stacking amorphous silicon (a-Si) and the inorganic insulating material.

Next, referring to FIG. 9C, the light-emitting element 160 can be transferred over the first lower base portion 110a of the lower base substrate 110. The light-emitting element 160 can be electrically connected to the lower connection line 146.

Then, referring to FIG. 9D, the intermediate layer 310 can be formed by coating a soft material containing the conductive balls 320 over the lower base substrate 110 on which the light-emitting element 160 is transferred.

Next, referring to FIG. 9E, the intermediate layer 310 and the conductive balls 320 can be partially removed using a first mechanism 510. In this case, the intermediate layer 310 and the conductive balls 320 can be removed by a squeezing method.

Accordingly, referring to FIG. 9F, the conductive balls 320 can be disposed over the lower connection line 146 and may not be disposed over the light-emitting element 160.

Next, referring to FIG. 10A, a second carrier substrate 420 can be provided, and an upper surface of the second carrier substrate 420 can be selectively removed by irradiating a laser, thereby forming a plurality of second concave portions 420b on the upper surface of the second carrier substrate 420. Here, the second carrier substrate 420 can be formed of glass.

Next, referring to FIG. 10B, the upper base substrate 210 can be formed on the second carrier substrate 420 to correspond to each of the second concave portions 420a. The light-blocking layer 220 can be formed on the upper base substrate 210. The light-blocking layer 220 can be formed by coating a resin containing a black pigment and/or carbon black.

As described above, the portions of the upper base substrate 210 and the light-blocking layer 220 corresponding to the first and third link portions B1 and B3 can be inclined with respect to the portions of the upper base substrate 210 and the light-blocking layer 220 corresponding to the second link portion B2.

Meanwhile, a sacrificial layer can be further provided between the second carrier substrate 420 and the upper base substrate 210.

Then, referring to FIG. 10C, the upper connection line 230 can be formed over the light-blocking layer 220. The upper connection line 230 can be formed along the inclination of the light-blocking layer 220 and the upper base substrate 210.

Next, referring to FIG. 11A, the second carrier substrate 420 provided with the upper connection line 230 of FIG. 10C can be disposed over the first carrier substrate 410 provided with the intermediate layer 310 of FIG. 9F, and the first carrier substrate 410 and the second carrier substrate 420 can be attached through the intermediate layer 310. In this case, the upper connection line 230 can be spaced apart from the light-emitting element 160 and overlap the lower connection line 146. The conductive balls 320 can be disposed between the lower connection line 146 and the upper connection line 230 overlapping each other.

Next, referring to FIG. 11B, the first carrier substrate 410 can be separated to expose the lower base substrate 110. In this case, the first carrier substrate 410 can be separated by irradiating a laser from a lower side of the first carrier substrate 410, and the sacrificial layer can also be removed. The separated first carrier substrate 410 can be reused.

Next, referring to FIG. 11C, the first flexible substrate 102 can be formed by coating a soft material on an outer surface of the exposed lower base substrate 110. The first flexible substrate 102 can be partially removed using a second mechanism 520. In this case, the first flexible substrate 102 can be removed by a squeezing method.

Then, referring to FIG. 11D, the first flexible substrate 102 with a reduced thickness by being partially removed can be cured.

Next, referring to FIG. 11E, the second carrier substrate 420 can be separated to expose the upper base substrate 210. In this case, the second carrier substrate 420 can be separated by irradiating a laser from an upper side of the second carrier substrate 420, and the sacrificial layer can also be removed. The separated second carrier substrate 420 can be reused.

Next, referring to FIG. 11F, the second flexible substrate 202 can be formed by coating a soft material on an outer surface of the exposed upper base substrate 210. Then, the second flexible substrate 202 can be partially removed using a third mechanism 530. In this case, the second flexible substrate 202 can be removed by a squeezing method.

Next, referring to FIG. 11G, the second flexible substrate 202 with a reduced thickness by being partially removed can be cured, thereby completing the stretchable display device 100 according to the embodiments of the present disclosure.

As such, the stretchable display device 100 according to the embodiments of the present disclosure can be manufactured by forming the lower substrate and the upper substrate through respective processes and then attaching the lower substrate and the upper substrate.

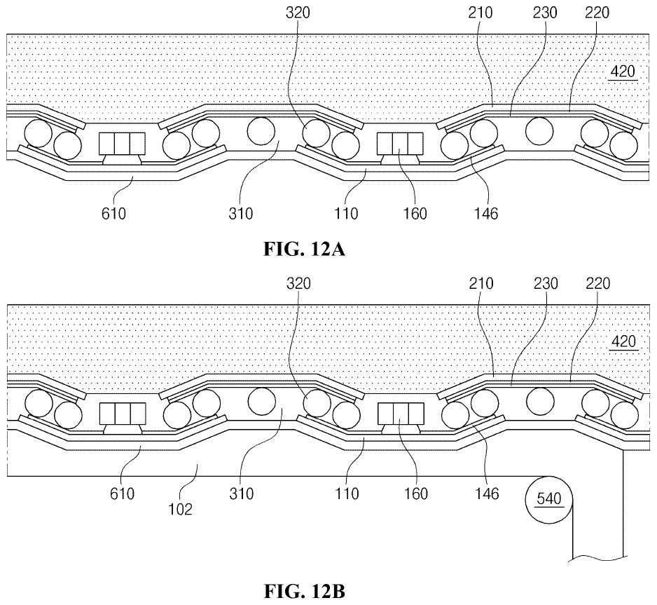

Meanwhile, in the previous embodiment, the first flexible substrate 102 can be formed by coating a soft material. However, the first flexible substrate 102 can be formed by laminating a flexible film. Another embodiment of the present disclosure will be described with reference to FIGS. 12A and 12B.

FIGS. 12A and 12B are schematic cross-sectional views of a stretchable display device in steps of manufacturing the same according to another embodiment of the present disclosure. A method of manufacturing the stretchable display device according to another embodiment of the present disclosure has substantially the same configuration as that of the previous embodiment, except for the step of forming the first flexible substrate of FIG. 11C. The same parts as those of the previous embodiments are designated by the same or similar reference signs, and explanation for the same parts can be shortened or omitted.

Referring to FIG. 12A, an adhesive layer 610 can be formed on the outer surface of the lower base substrate 110 exposed through the step of FIG. 11B. The adhesive layer 610 can be in contact with the lower base substrate 110 and the intermediate layer 310 and can have a uniform thickness. For example, the adhesive layer 610 can be formed of an optically clear adhesive (OCA) or an optically clear resin (OCR). Alternatively, the adhesive layer 610 can be formed of a pressure sensitive adhesive (PSA).

Next, referring to FIG. 12B, a flexible film can be disposed under the adhesive layer 610 and laminated using a fourth mechanism 540 such as a roller, thereby forming the first flexible substrate 102.

Accordingly, the adhesive layer 610 can be disposed between the lower base substrate 110 and the first flexible substrate 102, and the first flexible substrate 102 can be attached to the lower base substrate 110 through the adhesive layer 610.

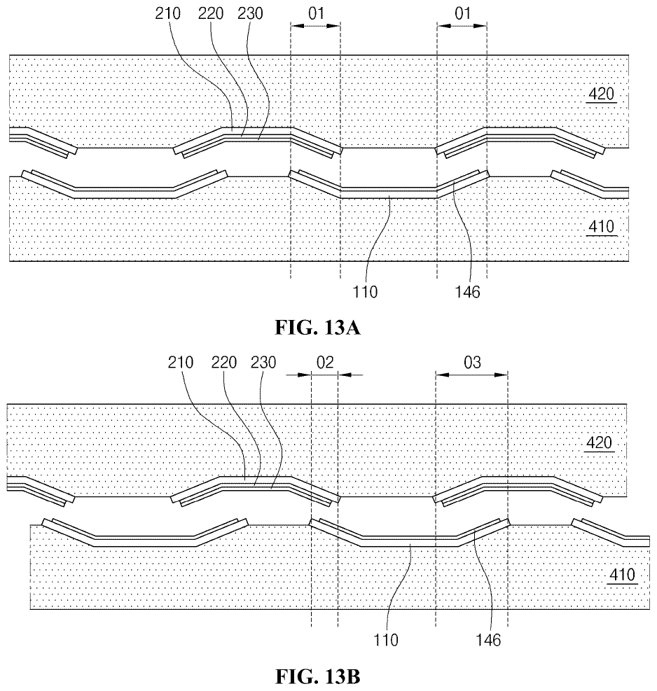

In the stretchable display device 100 according to the embodiments of the present invention, misalignment can occur during the process of attaching the lower substrate and the upper substrate. This will be described with reference to FIGS. 13A and 13B.

FIG. 13A is a schematic cross-sectional view of a stretchable display device ideally aligned according to an embodiment of the present invention, and FIG. 13B is a schematic cross-sectional view of a stretchable display device misaligned according to an embodiment of the present invention.

Referring to FIG. 13A, when the lower base substrate 110 and the upper base substrate 210 are ideally aligned, an overlap width O1 of the lower base substrate 110 and the upper base substrate 210 can be constant. For example, the overlap width O1 of one lower base substrate 110 overlapping two upper base substrates 210 adjacent thereto can be the same.

On the other hand, referring to FIG. 13B, when misalignment occurs, overlap widths O2 and O3 of the lower base substrate 110 and the upper base substrate 210 can be different from each other. For example, a first overlap width O2 of one lower base substrate 110 overlapping one of two upper base substrates 210 adjacent thereto can be different from a second overlap width O3 of the one lower base substrate 110 overlapping the other of the two upper base substrates 210 adjacent thereto. The first overlap width O2 can be smaller than the second overlap width O3.

Here, the first overlap width O2 can be a minimum overlap width of the lower base substrate 110 and the upper base substrate 210. It is preferable that the minimum overlap width O2 be larger than the diameter of the conductive ball 320. Since the diameter of the conductive ball 320 is relatively small, the lower connect line 146 and the upper connection line 230 can be electrically connected to each other even if misalignment occurs.

For example, the diameter of the conductive ball 320 can be 3 μm to 15 μm, and preferably, 5 μm to 10 μm.

The stretchable display device according to aspects of the present disclosure can be stretched without changing the shape of the connection line by connecting adjacent pixels through the connection line provided on a different substrate from the pixels, so that the connection line can be prevented from being damaged even after repeated stretching.

In addition, according to aspects of the present disclosure, by providing the base substrate between the connection line and the flexible substrate, damage to the connection line due to external impacts can be prevented.

Accordingly, in the display device of the present disclosure, the power consumption can be reduced due to the improved lifetime, thereby achieving the low power consumption.

It will be apparent to those skilled in the art that various modifications and variations can be made in the electroluminescent display device and the method of manufacturing the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A stretchable display device comprising:
a lower base substrate in which a rigid portion and a soft portion are defined;
a light-emitting element disposed in the rigid portion;
a lower connection line disposed in the soft portion;
an upper base substrate disposed on the lower base substrate; and
an upper connection line disposed on the upper base substrate,
wherein the upper connection line is electrically connected to the lower connection line.

2. The stretchable display device of claim 1, wherein the lower base substrate includes a first base portion corresponding to the rigid portion and a second base portion corresponding to the soft portion, and
wherein the second base portion is inclined with an inclination angle with respect to the first base portion.

3. The stretchable display device of claim 1, wherein first, second, and third link portions are defined in the upper base substrate, and
wherein the first link portion overlaps the soft portion of the lower base substrate, and the third link portion overlaps a soft portion of another lower base substrate.

4. The stretchable display device of claim 3, wherein a portion of the upper base substrate corresponding to each of the first and third link portions is inclined with an inclination angle with respect to a portion of the upper base substrate corresponding to the second link portion.

5. The stretchable display device of claim 1, further comprising a light-blocking layer disposed between the upper base substrate and the upper connection line.

6. The stretchable display device of claim 1, wherein the upper base substrate is spaced apart from the rigid portion and overlaps the soft portion.

7. The stretchable display device of claim 6, wherein the upper base substrate includes a horizontal base substrate and a vertical base substrate, and
wherein a distance between the horizontal base substrate and the vertical base substrate adjacent to each other increases as a distance from the rigid portion increases.

8. The stretchable display device of claim 1, wherein the soft portion includes a horizontal soft portion and a vertical soft portion, and
wherein a distance between the horizontal soft portion and the vertical soft portion adjacent to each other increases as a distance from the rigid portion increases.

9. The stretchable display device of claim 1, further comprising an intermediate layer disposed between the lower base substrate and the upper base substrate and containing conductive balls,
wherein the conductive balls are disposed between the lower connection line and the upper connection line.

10. The stretchable display device of claim 9, wherein a minimum overlap width of the lower base substrate and the upper base substrate is greater than a diameter of each of at least one of the conductive balls.

11. The stretchable display device of claim 1, further comprising:
a first flexible substrate disposed on an outer surface of the lower base substrate; and
a second flexible substrate disposed on an outer surface of the upper base substrate,
wherein each of the first flexible substrate and the second flexible substrate has different thicknesses depending on a location.

12. The stretchable display device of claim 11, wherein the first flexible substrate and the second flexible substrate have different minimum thicknesses.

13. The stretchable display device of claim 12, wherein the minimum thickness of the second flexible substrate is smaller than the minimum thickness of the first flexible substrate.

14. A method of manufacturing a stretchable display device, the method comprising:
forming a lower base substrate in which a rigid portion and a soft portion are defined;
forming a lower connection line in the soft portion;
transferring a light-emitting element in the rigid portion;
forming an upper base substrate;
forming an upper connection line on the upper base substrate; and
attaching the lower base substrate and the upper base substrate so that the upper connection line and the lower connection line overlap and face each other, and
wherein the upper base substrate is spaced apart from the rigid portion and overlaps the soft portion.

15. The method of claim 14, further comprising forming an intermediate layer containing conductive balls after transferring the light-emitting element,
wherein the conductive balls are disposed between the lower connection line and the upper connection line and are not disposed on the light-emitting element.

16. The method of claim 14, further comprising:
forming a first flexible substrate on an outer surface of the attached lower base substrate; and
forming a second flexible substrate on an outer surface of the attached upper base substrate,
wherein each of the first flexible substrate and the second flexible substrate has different thicknesses depending on a location.

17. The method of claim 16, further comprising forming an adhesive layer between the lower base substrate and the first flexible substrate.

18. The method of claim 14, further comprising:
preparing a first carrier substrate disposed with a first concave portion; and
preparing a second carrier substrate disposed with a second concave portion,
wherein the lower base substrate is formed on the first carrier substrate corresponding to the first concave portion, and the upper base substrate is formed on the second carrier substrate corresponding to the second concave portion.

19. The method of claim 15, wherein a minimum overlap width of the lower base substrate and the upper base substrate is greater than a diameter of each of at least one of the conductive balls.
